(19) United States
(12) Patent Application Publication
(10) Pub. No.: US 2026/0082602 A1
(43) Pub. Date: Mar. 19, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Yoichi HORI, Himeji Hyogo (JP); Sozo KANIE, Himeji Hyogo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/039,866

(22) Filed: Jan. 29, 2025

(30) Foreign Application Priority Data
Sep. 17, 2024 (JP) 2024-160312

(51) Int. Cl. H10D 8/60; H10D 62/60; H10D 62/832; H10D 64/23; H10D 64/62; H10D 64/64

(52) U.S. Cl. CPC H10D 8/60; H10D 62/60; H10D 64/23; H10D 62/8325; H10D 64/62; H10D 64/64

(57) ABSTRACT

A semiconductor device according to an embodiment includes a silicon carbide layer, a first electrode, a second electrode, a first semiconductor region with a first conductivity type, a second and third semiconductor region with a second conductivity type, a first conductive part, and a second conductive part. The silicon carbide layer includes a main body part and a protruding part that protrudes from the main body part. The first semiconductor region is provided inside the main body part. The second semiconductor region is provided inside the protruding part. The third semiconductor region is provided from the second semiconductor region up to an upper end of the protruding part, and has an impurity concentration higher than that of the second semiconductor region. The first conductive part is in Schottky contact with the first semiconductor region. The second conductive part is in ohmic contact with the third semiconductor region.

### CROSS-REFERENCE TO RELATED APPLICATIONS

This application is based upon and claims the benefit of priority from the prior Japanese Patent Application No.2024-160312, filed on Sep. 17, 2024; the entire contents of which are incorporated herein by reference.

### FIELD

Embodiments described herein relate generally to a semiconductor device.

### BACKGROUND

In a Schottky Barrier Diode (SBD) formed by joining a metal and a semiconductor, it is desirable to improve a surge withstand capability.

### BRIEF DESCRIPTION OF THE DRAWINGS

FIG. 1 is a cross-sectional view of a semiconductor device according to a first embodiment;

FIG. 2 is an enlarged view of protruding parts in the semiconductor device according to the first embodiment;

FIG. 3A is a cross-sectional view for explaining an example of a manufacturing process of the semiconductor device according to the first embodiment;

FIG. 3B is a cross-sectional view for explaining an example of the manufacturing process of the semiconductor device according to the first embodiment, subsequent to FIG. 3A;

FIG. 3C is a cross-sectional view for explaining an example of the manufacturing process of the semiconductor device according to the first embodiment, subsequent to FIG. 3B;

FIG. 3D is a cross-sectional view for explaining an example of the manufacturing process of the semiconductor device according to the first embodiment, subsequent to FIG. 3C;

FIG. 3E is a cross-sectional view for explaining an example of the manufacturing process of the semiconductor device according to the first embodiment, subsequent to FIG. 3D;

FIG. 3F is a cross-sectional view for explaining an example of the manufacturing process of the semiconductor device according to the first embodiment, subsequent to FIG. 3E;

FIG. 3G is a cross-sectional view for explaining an example of the manufacturing process of the semiconductor device according to the first embodiment, subsequent to FIG. 3F;

FIG. 3H is a cross-sectional view for explaining an example of the manufacturing process of the semiconductor device according to the first embodiment, subsequent to FIG. 3G;

FIG. 3I is a cross-sectional view for explaining an example of the manufacturing process of the semiconductor device according to the first embodiment, subsequent to FIG. 3H;

FIG. 3J is a cross-sectional view for explaining an example of the manufacturing process of the semiconductor device according to the first embodiment, subsequent to FIG. 3I;

FIG. 3K is a cross-sectional view for explaining an example of the manufacturing process of the semiconductor device according to the first embodiment, subsequent to FIG. 3J;

FIG. 3L is a cross-sectional view for explaining an example of the manufacturing process of the semiconductor device according to the first embodiment, subsequent to FIG. 3K;

FIG. 4 is a cross-sectional view of a semiconductor device according to a modification of the first embodiment;

FIG. 5 is a plan view of a semiconductor device according to a second embodiment;

FIG. 6 is a cross-sectional view of a semiconductor device according to a second embodiment;

FIG. 7 is a plan view of a semiconductor device according to a modification of the second embodiment;

FIG. 8 is a cross-sectional view of the semiconductor device according to the modification of the second embodiment; and

FIG. 9 is a cross-sectional view of a semiconductor device according to a third embodiment.

### DETAILED DESCRIPTION

A semiconductor device according to an embodiment includes a silicon carbide layer, a first electrode, a second electrode, a first semiconductor region with a first conductivity type, a second semiconductor region with a second conductivity type, a third semiconductor region with the second conductivity type, a first conductive part, and a second conductive part. The silicon carbide layer includes a main body part and a protruding part that protrudes from the main body part. The first electrode is provided on the protruding part. The second electrode is provided opposite to the first electrode with the main body part interposed therebetween. The first semiconductor region is provided inside the main body part, and electrically connected to the second electrode. The second semiconductor region is provided inside the protruding part. The third semiconductor region is provided inside the protruding part from the second semiconductor region up to an upper end of the protruding part, and has an impurity concentration higher than that of the second semiconductor region. The first conductive part is in Schottky contact with the first semiconductor region, and electrically connected to the first electrode. The second conductive part is in ohmic contact with the third semiconductor region at the upper end of the protruding part, and electrically connected to the first electrode.

Hereinafter, embodiments according to the present invention will be described with reference to the drawings. The embodiments do not limit the present invention. The drawings are schematic or conceptual, and the ratio of each portion and the like are not necessarily the same as actual ones. In the specification and the drawings, elements similar to those described above with respect to the previously described drawings are denoted by the same reference numerals, and the detailed description thereof is appropriately omitted.

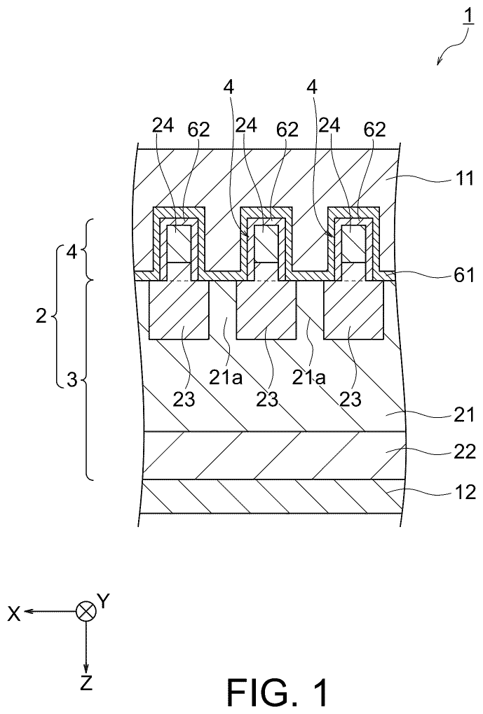

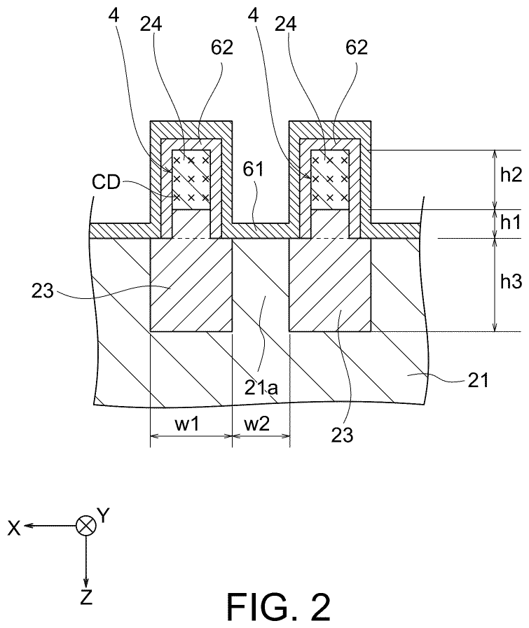

In addition, for convenience of description, an XYZ orthogonal coordinate system is adopted as illustrated in FIGS. 1 and 2, and the like. A Z-axis direction is a stacking direction (thickness direction) of the semiconductor device. In addition, in the Z-axis direction, an anode electrode side is also referred to as “upper”, and a cathode electrode side is also referred to as “lower”. However, this expression is for convenience and independent of the direction of gravity. The Z-axis direction is a first direction in the claims. A Y-axis direction is a second direction in the claims. An X-axis direction is a third direction in the claims.

In addition, in the following description, notations of n⁺⁺, n⁺, n, and n⁻, and p⁺⁺, p⁺, p, and p⁻may be used to represent the relative level of impurity concentration in each conductivity type. That is, n⁺⁺ indicates that an n-type impurity concentration is relatively higher than n⁺, n⁺ indicates that the n-type impurity concentration is relatively higher than n, and n⁻ indicates that the n-type impurity concentration is relatively lower than n. In addition, p⁺⁺ indicates that a p-type impurity concentration is relatively higher than p⁺, p⁺ indicates that the p-type impurity concentration is relatively higher than p, and p⁻ indicates that the p-type impurity concentration is relatively lower than p. When both a p-type impurity and an n-type impurity are contained in each region, each of these notations represents a relative level of a net impurity concentration after these impurities are compensated for each other. The n-type, n++-type, n⁺-type, and n⁻-type are examples of a first conductivity type in the claims. The p-type, p⁺⁺-type, p⁺-type, and p⁻-type are examples of a second conductivity type in the claims. Note that in the following description, the n-type and the p-type may be reversed. That is, the first conductivity type may be the p-type.

In addition, the impurity concentration of the semiconductor region can be measured by, for example, secondary ion mass spectrometry (SIMS). In addition, the relative level of the impurity concentration can also be determined from the level of a carrier concentration obtained by, for example, scanning capacitance microscopy (SCM).

In addition, a dimension of the protruding part such as a width can be measured by, for example, analyzing a surface and a cross section of a semiconductor device with an optical microscope, a transmission electron microscope (TEM), an energy dispersive X-ray spectroscopy (EDX), or a scanning electron microscope (SEM).

Note that terms such as “identical”, “same”, and “equal”, dimensions, values of physical characteristics, and the like, which specify shapes, geometric conditions, physical characteristics, and the degrees thereof, used in the present specification, are interpreted including a range in which similar functions can be expected, without being bound by a strict meaning.

### First Embodiment

A semiconductor device 1 according to a first embodiment will be described with reference to FIG. 1. FIG. 1 is a cross-sectional view of the semiconductor device 1 according to the first embodiment.

The semiconductor device 1 according to the present embodiment is a Schottky Barrier Diode (SBD). As illustrated in FIG. 1, the semiconductor device 1 includes a silicon carbide layer 2, an anode electrode 11, a cathode electrode 12, a Schottky electrode part 61, and an ohmic electrode part 62.

The silicon carbide layer 2 may be formed of an epitaxial layer or a semiconductor substrate, or a semiconductor substrate and an epitaxial layer disposed on the semiconductor substrate. The silicon carbide layer 2 is made of single crystal silicon carbide (SiC). As an n-type impurity in the silicon carbide layer 2, for example, nitrogen (N), phosphorus (P), arsenic (As), or antimony (Sb) is used, and as a p-type impurity for example, aluminum (Al) or boron (B) is used.

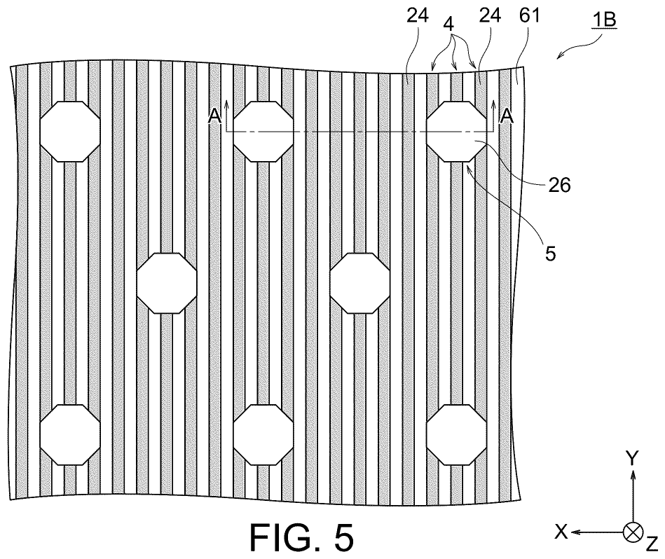

The silicon carbide layer 2 is provided with a main body part 3 and a protruding part 4. The main body part 3 has an upper surface (first main surface) and a lower surface (second main surface). The protruding part 4 protrudes from the upper surface of the main body part 3. A dotted line in FIG. 1 indicates the boundary between the main body part 3 and the protruding part 4. As illustrated in FIG. 5 described later, the protruding part 4 extends in the Y-axis direction. In the present embodiment, a plurality of protruding parts 4 protrudes from the upper surface of the main body part 3. The plurality of protruding parts 4 is disposed to be spaced from each other along the X-axis direction, and the Schottky electrode part 61 is provided therebetween. Note that, in the present embodiment, an island-shaped part 5 described later is not provided.

As illustrated in FIG. 1, an n region 21, an n⁺ region 22, a p region 23, and a p⁺ region 24 are provided in the silicon carbide layer 2.

The n region 21 is an n-type semiconductor region in the SBD. The n⁺ region 22 is an n⁺-type semiconductor region in the SBD. In the main body part 3, the n region 21 and the n⁺ region 22 are provided from the upper surface of the main body part 3 up to the lower surface of the main body part 3. More specifically, the n region 21 is provided from the upper surface of the main body part 3 up to the middle of the main body part 3, and the n⁺ region 22 is provided from the n region 21 up to the lower surface of the main body part 3. The n⁺ region 22 is in contact with the cathode electrode 12 and electrically connected to the cathode electrode 12. The n region 21 and the n⁺ region 22 constitute an example of a first semiconductor region in the claims. The n-type impurity concentration of the n region 21 is, for example, 1×10¹⁵ cm⁻³ or more and 2×10¹⁶ cm⁻³ or less. The n-type impurity concentration of the n⁺ region 22 is higher than the n-type impurity concentration of the n region 21. The n-type impurity concentration of the n⁺ region 22 is, for example, 1×10¹⁸ cm⁻³ or more and 1×10²¹ cm⁻³ or less.

Note that the n⁺ region 22 may not be provided. In this case, the n region 21 is directly provided on the cathode electrode 12, and the cathode electrode 12 is electrically connected to the n region 21. Alternatively, the n region 21 may not be provided. In this case, for example, the n⁺ region 22 is also provided at the position of the n region 21.

The p region 23 is a p-type semiconductor region. Since the p region 23 is provided, the semiconductor device 1 includes a so-called Junction Barrier Schottky (JBS) structure. The p region 23 is provided inside the protruding part 4. More specifically, the p region 23 is provided from the inside of the protruding part 4 up to the middle of the main body part 3 through the upper surface of the main body part 3. That is, the p region 23 has a lower portion provided inside the main body part 3 and an upper portion that protrudes from the upper surface of the main body part 3 and is provided up to the middle of the protruding part 4. As indicated by a dotted line in FIG. 1, the boundary between the main body part 3 and the protruding part 4 is positioned inside the p region 23. In other words, the p region 23 spans the boundary. The p region 23 is an example of a second semiconductor region in the claims. The p region 23 extends in the Y-axis direction. The p-type impurity concentration of the p region 23 is lower than the p-type impurity concentration of the p⁺ region 24. The p-type impurity concentration of the p region 23 is, for example, 1×10¹⁶ cm⁻³ or more and 1×10¹⁹ cm⁻³ or less.

In the present embodiment, a plurality of p regions 23 is provided. Each p region 23 is provided from the inside of the protruding part 4 up to the middle of the main body part 3 through the upper surface of the main body part 3. In addition, the n region 21 has a plurality of portions 21a. Each portion 21a is sandwiched between the p regions 23 adjacent to each other, and the upper end thereof is positioned to be aligned with the upper surface of the main body part 3. The portions 21a are so-called mesa portions. The portions 21a are in contact with the Schottky electrode part 61.

The p⁺ region 24 is a p⁺-type semiconductor region. Since the p⁺ region 24 is provided, the semiconductor device 1 includes a so-called Merged PiN Schottky (MPS) structure. The p⁺ region 24 is provided inside the protruding part 4 from the p region 23 to the upper end of the protruding part 4. The p⁺ region 24 is in contact with the p region 23. The boundary between the p⁺ region 24 and the p region 23 is positioned above the upper surface of the main body part 3. The p⁺ region 24 is an example of a third semiconductor region in the claims. The p⁺ region 24 extends in the Y-axis direction. The p-type impurity concentration of the p⁺ region 24 is higher than the p-type impurity concentration of the p region 23. The p-type impurity concentration of the p⁺ region 24 is, for example, 5×10¹⁸ cm⁻³ or more and 1×10²¹ cm⁻³ or less. In the present embodiment, the p⁺ region 24 is provided up to side ends of the protruding part 4.

The anode electrode 11 functions as an anode electrode of the SBD. The anode electrode 11 is provided over the upper surface of the main body part 3 such that the protruding part 4 is embedded. That is, a part of the anode electrode 11 is provided on the protruding part 4 and the other part of the anode electrode 11 enters between the adjacent protruding parts 4. The anode electrode 11 is an example of a first electrode in the claims. The anode electrode 11 contains, for example, aluminum (Al), titanium (Ti), copper (Cu), tungsten (W), or the like.

The cathode electrode 12 functions as a cathode electrode of the SBD. The cathode electrode 12 is provided on the lower surface of the main body part 3. That is, the cathode electrode 12 is provided opposite to the anode electrode 11 with the main body part 3 interposed therebetween. The cathode electrode 12 is an example of a second electrode in the claims. The cathode electrode 12 contains, for example, aluminum (Al), titanium (Ti), copper (Cu), tungsten (W), or the like.

The Schottky electrode part 61 is a conductive part provided on the upper surface of the main body part 3. More specifically, the Schottky electrode part 61 covers the upper surface of the main body part 3 exposed between the protruding parts 4, the upper surface of the ohmic electrode part 62, and the side surfaces of the ohmic electrode part 62. The Schottky electrode part 61 is in Schottky contact with the n region 21 at the upper surface of the main body part 3. More specifically, the Schottky electrode part 61 is in contact with the portions 21a of the n region 21 and is in Schottky contact with the portions 21a of the n region 21 at portions of the upper surface of the main body part 3, each of which is sandwiched between the adjacent protruding parts 4. In addition, the Schottky electrode part 61 is electrically connected to the anode electrode 11. The Schottky electrode part 61 is an example of a first conductive part in the claims. The Schottky electrode part 61 contains, for example, molybdenum (Mo), titanium (Ti), vanadium (V), nickel (Ni), platinum (Pt), or the like.

The ohmic electrode part 62 is a conductive part provided on the protruding part 4. The ohmic electrode part 62 is in ohmic contact with the p⁺ region 24 at least at the upper end of the protruding part 4. In the present embodiment, the ohmic electrode part 62 is in ohmic contact with the p⁺ region 24 at the upper end and the side ends of the protruding part 4. In addition, the ohmic electrode part 62 is electrically connected to the anode electrode 11 via the Schottky electrode part 61. The ohmic electrode part 62 is an example of a second conductive part in the claims. The ohmic electrode part 62 contains, for example, nickel silicide (NiSi), titanium silicide (TiSi), or the like.

Next, the configuration of the protruding part 4 and the periphery thereof in the semiconductor device 1 will be described in detail with reference to FIG. 2. FIG. 2 is an enlarged view of the protruding parts 4 in the semiconductor device 1 according to the first embodiment.

As illustrated in FIG. 2, the protruding part 4 protrudes from the upper surface of the main body part 3 by a height equal to the sum of a height h1 and a height h2. Here, the height h1 is a height of a portion (upper portion) of the p region 23 protruding from the upper surface of the main body part 3, and is, for example, 0.2 μm. The height h2 is a height of the p⁺ region 24, and is, for example, 0.2 μm. Therefore, in this case, the sum of the height h1 and the height h2 is 0.4 μm. The sum of the height h1 and the height h2 may be any value within a range of 0.3 μm to 1.0 μm. In addition, the sizes of the height h1 and the height h2 may be the same or either one may be larger.

A height h3 is a height of a portion (lower portion) of the p region 23 embedded in the main body part 3, and is, for example, 0.5 μm.

A width w1 is a width of the p region 23 at the upper surface of the main body part 3. The width w1 is, for example, 2 μm. A width w2 is a width of the portion 21a of the n region 21 at the upper surface of the main body part 3. The width w2 is, for example, 2μm. Note that each of the width w1 and the width w2 may be any value within a range of 1 μm to 8 μm, and more preferably any value within a range of 1 μm to 2 μm.

Note that, in the example of FIG. 2, the side surfaces of the p⁺ region 24 and the side surfaces of the portion of the p region 23 protruding from the upper surface of the main body part 3 are substantially perpendicular to the upper surface of the main body part 3. Furthermore, a width of the p⁺ region 24 is equal to the width of the portion of the p region 23 protruding from the upper surface of the main body part 3. Without being limited thereto, the protruding part 4 may have a shape in which the width is narrower toward the upper end of the protruding part 4.

In addition, in the example of FIG. 2, the side surfaces of the portion of the p region 23 embedded in the main body part 3 is substantially perpendicular to the upper surface of the main body part 3, and the width of the p region 23 in the main body part 3 is substantially equal to the width w1 of the p region 23 at the upper surface of the main body part 3. Without being limited thereto, the width of the p region 23 in the main body part 3 may be different from the width w1 at the upper surface of the main body part 3.

As illustrated in FIG. 2, implantation defects CD such as interstitial atoms are formed in the p⁺ region 24. The implantation defects CD are generated in the p⁺ region 24 in a case where the p⁺ region 24 having a high impurity concentration is formed. In the present embodiment, the p⁺ region 24 is spaced from the n region 21 by the p region 23. That is, the n region 21 is not in direct contact with the p⁺ region 24 including the implantation defects CD.

As described above, the semiconductor device 1 according to the first embodiment includes the silicon carbide layer 2, the anode electrode 11, the cathode electrode 12, the n region 21 and n⁺ region 22 with the first conductivity type, the p region 23 with the second conductivity type, the p⁺ region 24 with the second conductivity type, the Schottky electrode part 61, and the ohmic electrode part 62. The silicon carbide layer 2 includes the main body part 3 and the protruding part 4 that protrudes from the main body part 3. The anode electrode 11 is provided on the protruding parts 4. The cathode electrode 12 is provided opposite to the anode electrode 11 with the main body part 3 interposed therebetween. The n⁺ region 22 is provided inside the main body part 3 and electrically connected to the cathode electrode 12. The p region 23 is provided inside the protruding part 4. The p⁺ region 24 is provided inside the protruding part 4 from the p region 23 to the upper end of the protruding part 4 and has an impurity concentration higher than that of the p region 23. The Schottky electrode part 61 is in Schottky contact with the n region 21, and electrically connected to the anode electrode 11. The ohmic electrode part 62 is in ohmic contact with the p⁺ region 24 at the upper end of the protruding part 4, and is electrically connected to the anode electrode 11.

According to the present embodiment, the p⁺ region 24 having an impurity concentration higher than that of the p region 23 is provided, and the ohmic electrode part 62 is in ohmic contact with the p⁺ region 24. Therefore, a p-n junction diode formed of the p⁺ region 24, the p region 23, the n region 21, and the n⁺ region 22 is turned on at the timing when a high current (high surge current) flows, and the current transport capability of the semiconductor device 1 is improved. As a result, the surge withstand capability of the semiconductor device 1 can be improved.

Furthermore, in the present embodiment, the p⁺ region 24 including the implantation defects CD is spaced from the n region 21 by the p region 23. Therefore, a leakage current (reverse current) during a reverse operation of the semiconductor device 1 can be controlled.

In addition, in the present embodiment, the p⁺ region 24 is provided inside the protruding part 4, and is not provided in the main body part 3. Therefore, in order to make the p⁺ region 24 spaced from the n region 21, it is not required to provide a p-type semiconductor region that surrounds the p⁺ region 24 in the main body part 3, for example. As a result, the area of the n region 21 in the upper surface of the main body part 3 can be secured, and an increase in the forward voltage can be avoided.

In addition, in the present embodiment, the plurality of p regions 23 is provided, and the n region 21 has the plurality of portions 21a, each of which is sandwiched between the p regions 23 and has an upper end positioned to be aligned with the upper surface of the main body part 3. As a result, the area where the Schottky electrode part 61 is in Schottky contact with the n region 21 can be increased, and the forward voltage of the semiconductor device 1 can be reduced.

### Method of Manufacturing Semiconductor Device 1

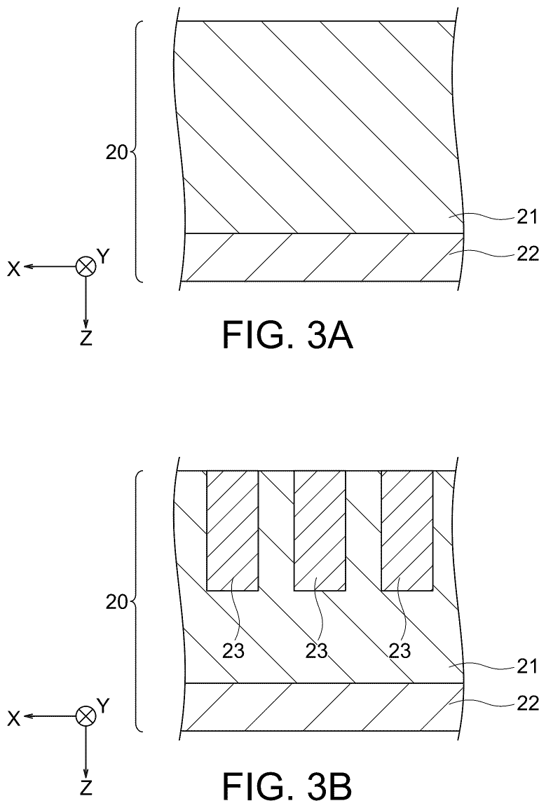

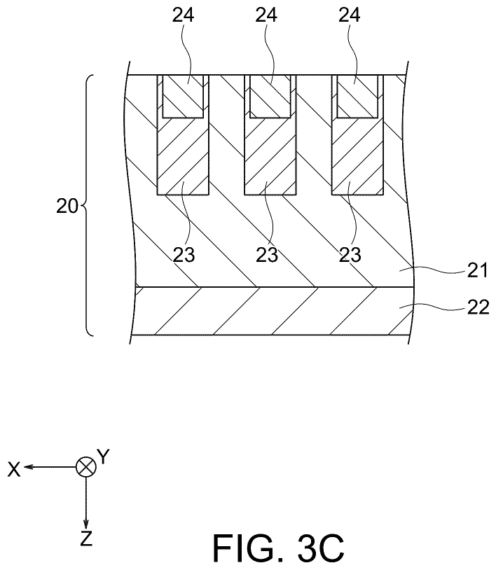

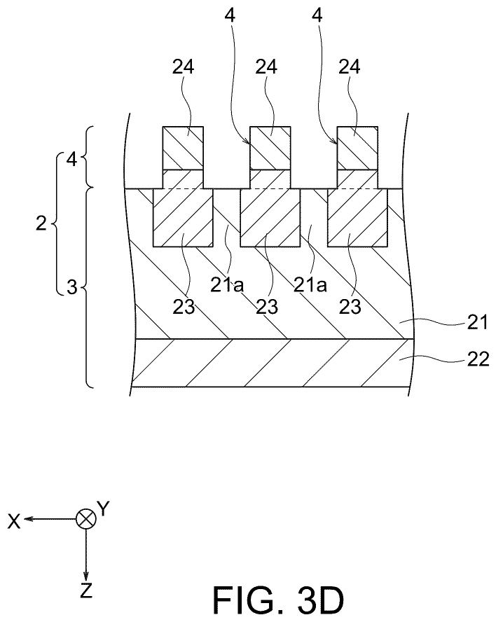

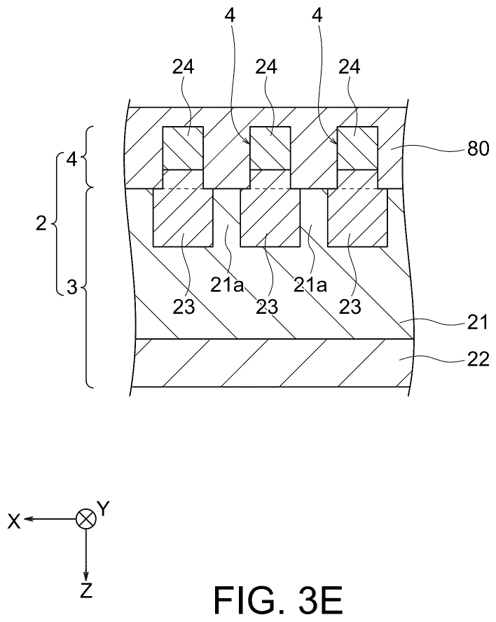

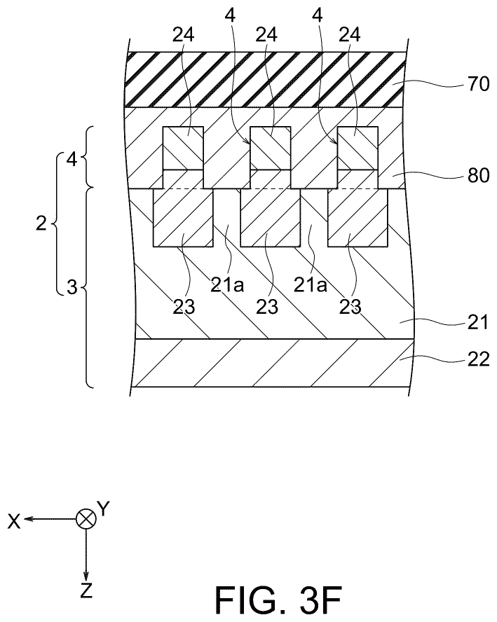

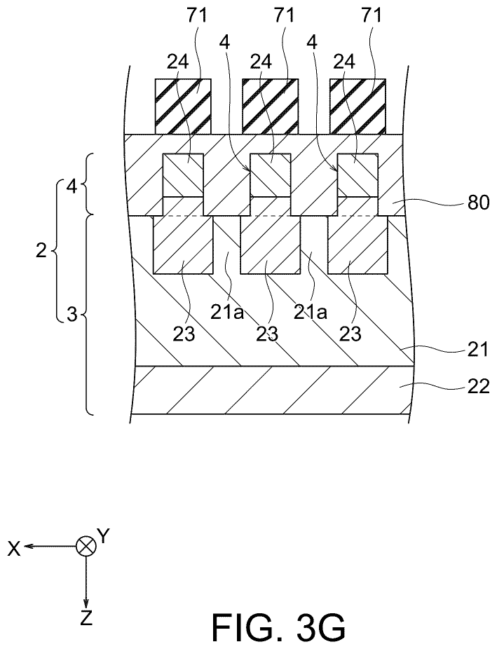

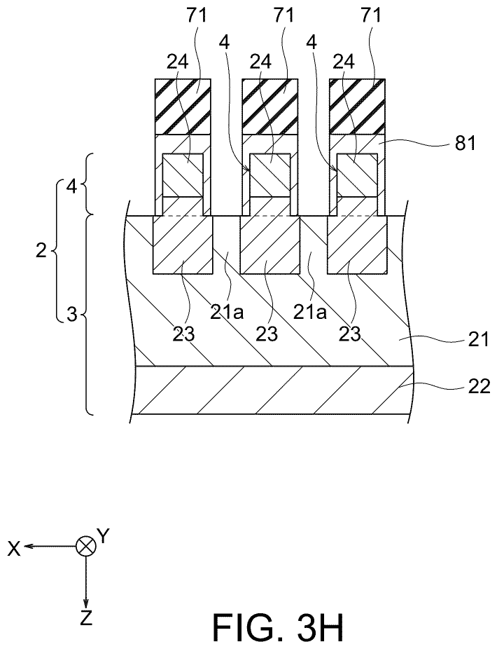

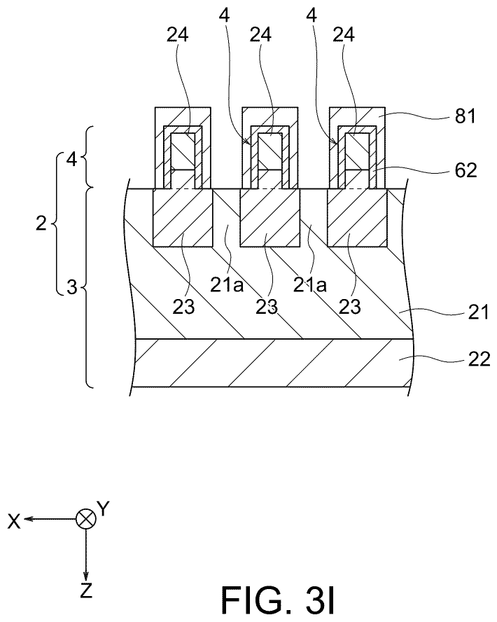

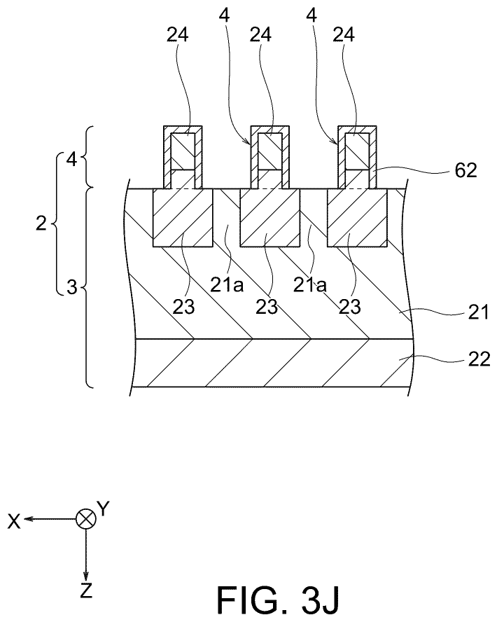

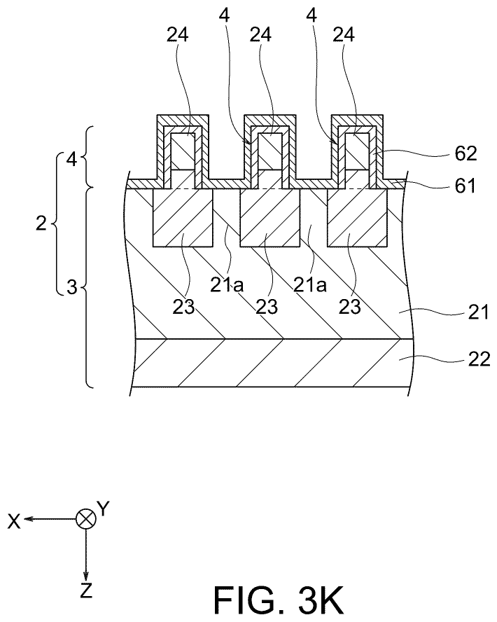

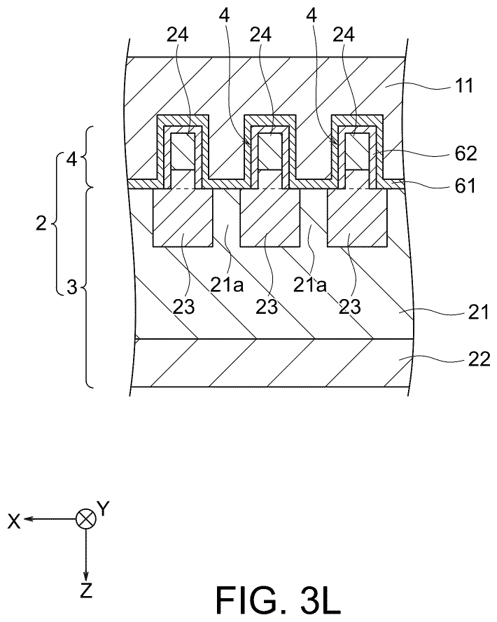

Next, an example of a method of manufacturing a semiconductor device 1 according to the first embodiment will be described with reference to FIGS. 3A to 3L. FIGS. 3A to 3L are cross-sectional views for describing the example of a manufacturing process of the semiconductor device 1 according to the first embodiment.

First, as illustrated in FIG. 3A, a silicon carbide layer 20 having an n region 21 and an n⁺ region 22 is prepared. The silicon carbide layer 20 includes, for example, the n⁺ region 22 and the n region 21 provided on the n⁺ region 22.

Next, as illustrated in FIG. 3B, ion implantation of p-type impurities is performed on a part of the upper surface of the silicon carbide layer 20 to form a p region 23. In the example of FIG. 3B, a plurality of the p regions 23 are formed to be spaced apart from each other. Ion implantation is performed by irradiation of a mask (not illustrated) with ions of p-type impurities, the mask being formed on the upper surface of the silicon carbide layer 20 and provided with openings in regions where the p regions 23 are to be formed.

Next, as illustrated in FIG. 3C, ion implantation of p-type impurities is performed on the upper surfaces of the p regions 23 within the upper surface of the silicon carbide layer 20 to form p⁺ regions 24. In the present embodiment, the p⁺ regions 24 are formed such that a width of the p⁺ region 24 is smaller than a width of the p region 23. Note that the p⁺ regions 24 may be formed such that the width of the p⁺ region 24 is equal to the width of the p region 23.

Next, as illustrated in FIG. 3D, a part of portions of the silicon carbide layer 20 sandwiched between the p regions 23 and the p⁺ regions 24 is removed by Reactive Ion Etching (RIE) or the like. More specifically, in the silicon carbide layer 20, a portion sandwiched between the p⁺ regions 24 and a portion sandwiched between the p regions 23 are removed. As a result, the silicon carbide layer 2 including the main body part 3 having the upper surface and the lower surface, and the protruding parts 4 protruding from the upper surface of the main body part 3 is formed. Note that the width of the protruding part 4 is smaller than the width of a portion of the p region 23 positioned inside the main body part 3.

Next, as illustrated in FIG. 3E, a metal material is deposited on the upper surface of the silicon carbide layer 2 by sputtering or the like. The metal material is, for example, nickel or titanium. As a result, a metal layer 80 is formed on the upper surface of the silicon carbide layer 2.

Next, as illustrated in FIG. 3F, a mask material 70 such as a resist is formed on the upper surface of the metal layer 80.

Next, as illustrated in FIG. 3G, the mask material 70 is patterned by photolithography or the like. As a result, mask patterns 71 are formed. The mask patterns 71 are provided above the protruding parts 4. In the present embodiment, a width of the mask pattern 71 formed is larger than the width of the protruding part 4.

Next, as illustrated in FIG. 3H, portions of the metal layer 80 that are not covered with the mask patterns 71 are removed by RIE or the like. As a result, the portions of the metal layer 80 positioned between the protruding parts 4 are removed, and metal parts 81 are formed. In the present embodiment, since the width of the mask pattern 71 is larger than the width of the protruding part 4, the metal part 81 remains at the side ends of the protruding part 4 in addition to the upper end of the protruding part 4.

Next, as illustrated in FIG. 3I, the mask patterns 71 are removed. Thereafter, the portions of the protruding parts 4 in contact with the metal parts 81 are silicided by heat treatment such as sintering. As a result of this process, an ohmic electrode part 62 such as nickel silicide or titanium silicide is formed at the upper end and side ends of the protruding part 4.

Next, as illustrated in FIG. 3J, the metal parts 81 are removed by wet etching (SH treatment) or the like by using sulfuric acid and a hydrogen peroxide solution.

Next, as illustrated in FIG. 3K, a conductive material is deposited on the upper surface of the silicon carbide layer 2 by sputtering or the like. The conductive material is molybdenum, titanium, vanadium, nickel, platinum, or the like. As a result, a Schottky electrode part 61 is formed on the upper surface of the main body part 3.

Next, as illustrated in FIG. 3L, an anode electrode 11 is formed on the upper surface of the silicon carbide layer 2 such that the Schottky electrode part 61 is embedded. Thereafter, although not illustrated, the cathode electrode 12 is formed on the lower surface of the silicon carbide layer 2.

Through the above process, the semiconductor device 1 is manufactured.

According to the manufacturing method of the present embodiment, since the width of the mask pattern 71 is larger than the width of the protruding part 4, the ohmic electrode part 62 can be more reliably formed at the side ends of the protruding part 4.

### Modification of First Embodiment

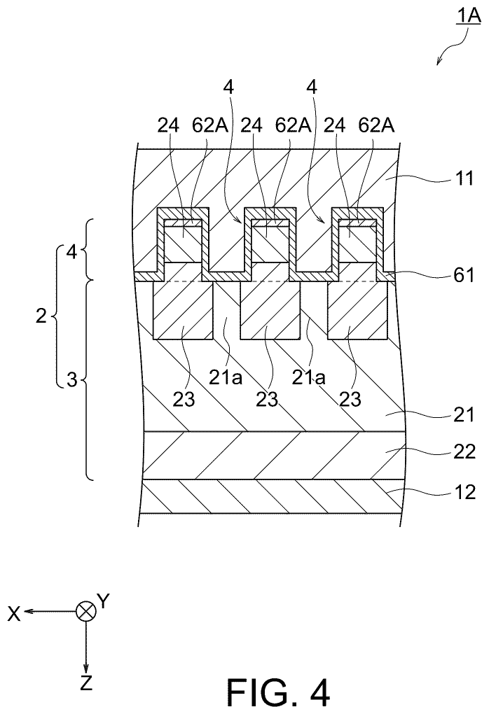

A semiconductor device 1A according to a modification of the first embodiment will be described with reference to FIG. 4. FIG. 4 is a cross-sectional view of the semiconductor device 1A according to the modification of the first embodiment. One of the differences between the present modification and the first embodiment described above is the shape of the ohmic electrode part. That is, an ohmic electrode part 62A of the present modification is not formed at the side ends of the protruding part 4 unlike the ohmic electrode part 62 of the first embodiment described above. Hereinafter, the semiconductor device 1A according to the present modification will be described focusing on the differences from the semiconductor device 1 according to the first embodiment.

As illustrated in FIG. 4, the ohmic electrode part 62A of the present modification is provided at the upper end of a protruding part 4. On the other hand, the ohmic electrode part 62A is not provided at the side ends of the protruding part 4. The ohmic electrode part 62A is made of, for example, the same material as the ohmic electrode part 62 of the first embodiment. Therefore, the ohmic electrode part 62A is in ohmic contact with the p⁺ region 24 at the upper end of the protruding part 4. Although not illustrated, the ohmic electrode part 62A may be provided at one side end of the protruding part 4 in addition to the upper end of the protruding part 4.

According to the present modification, although the area where the ohmic electrode part 62A is in ohmic contact with the p⁺ region 24 is reduced, the surge withstand capability of the semiconductor device 1A can be improved similarly to the first embodiment.

In the manufacturing process of the semiconductor device 1 according to the first embodiment described above, the semiconductor device 1A according to the present modification can be formed in a case where the width of the mask pattern 71 is equal to or less than the width of the protruding part 4, a case where the center position of the mask pattern 71 in the X-axis direction deviates from the center position of the protruding part 4, or the like. According to the present modification, the conditions of the manufacturing process of the semiconductor device 1A can be mitigated.

### Second Embodiment

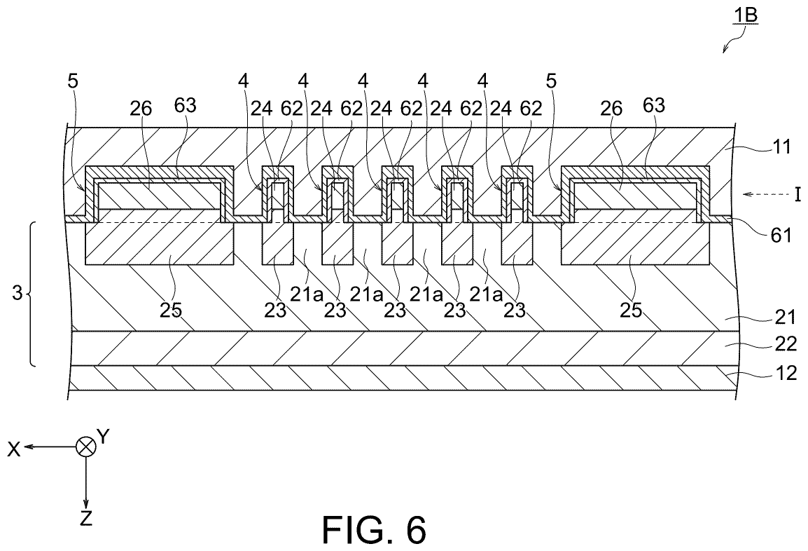

A semiconductor device 1B according to a second embodiment will be described with reference to FIGS. 5 and 6. FIG. 5 is a plan view of the semiconductor device 1B according to the second embodiment, and illustrates a plan view at a height position I in FIG. 6. FIG. 6 is a cross-sectional view of the semiconductor device 1B according to the second embodiment, taken along line A-A in FIG. 5. Note that, in FIG. 5, an ohmic electrode part 63 and a Schottky electrode part 61 provided at the side ends of an island-shaped part 5 are not illustrated. The semiconductor device 1B includes a dot-shaped (island-shaped) p-type semiconductor region (p region and p⁺ region) in addition to the semiconductor device 1 according to the first embodiment described above. Hereinafter, the semiconductor device 1B according to the present embodiment will be described focusing on the differences from the semiconductor device 1 according to the first embodiment.

As illustrated in FIGS. 5 and 6, a silicon carbide layer of the present embodiment further includes, in addition to the silicon carbide layer 2 of the first embodiment, an island-shaped part 5 that protrudes in an island shape on the upper surface of the main body part 3, that is, on the protruding part 4 side. Unlike the protruding part 4, the island-shaped part 5 does not extend in the X-axis direction and the Y-axis direction. More specifically, the lengths of the island-shaped part 5 in the X-axis direction and the Y-axis direction are both shorter than the length of the protruding part 4 extending in the Y-axis direction. On the other hand, the lengths of the island-shaped part 5 in the X-axis direction and the Y-axis direction are both longer than the length of the protruding part 4 extending in the X-axis direction. As illustrated in FIG. 5, in the present embodiment, the island-shaped part 5 is provided to span the plurality of protruding parts 4. As illustrated in FIG. 6, in the present embodiment, the island-shaped part 5 has the same cross-sectional structure as the protruding part 4, and has a larger width than that of the protruding part 4.

The island-shaped part 5 has an octagonal planar shape. Note that the planar shape of the island-shaped part 5 may be any shape such as a circle, a rectangle, or a polygon.

In addition, in the example of FIG. 5, the island-shaped part 5 is provided to span three protruding parts 4. Without being limited thereto, the island-shaped part 5 may be provided to span two protruding parts 4, or may be provided to span four or more protruding parts 4.

In addition, in the example of FIG. 5, both the left and right side surfaces of the island-shaped part 5 are parallel to the side surface of the protruding part 4. Without being limited thereto, at least one of the left or right side surface of the island-shaped part 5 may not be parallel to the side surfaces of the protruding part 4.

In addition, the arrangement of the island-shaped parts 5 illustrated in FIG. 5 is an example, and the arrangement of the island-shaped parts 5 is not limited to that illustrated in FIG. 5.

Furthermore, the example of FIG. 6, in the present embodiment, the upper end of the island-shaped part 5 has the same height as the upper end of the protruding part 4. The upper end of the island-shaped part 5 may have a height different from that of the upper end of the protruding part 4.

As illustrated in FIG. 6, the semiconductor device 1B according to the present embodiment further includes an island-shaped p region 25, an island-shaped p⁺ region 26, and an ohmic electrode part 63. The island-shaped part 5 has a structure in which the island-shaped p region 25, the island-shaped p⁺ region 26, and the ohmic electrode part 63 are sequentially stacked.

The island-shaped p region 25 is a p-type semiconductor region. The island-shaped p region 25 is a semiconductor region similar to the p region 23. The island-shaped p region 25 is provided inside the island-shaped part 5. More specifically, the island-shaped p region 25 is provided from the inside of the island-shaped part 5 up to the middle of the main body part 3 through the upper surface of the main body part 3. That is, the island-shaped p region 25 has a portion provided inside the main body part 3 and a portion that protrudes from the upper surface of the main body part 3 and is provided up to the middle of the island-shaped part 5. As indicated by a dotted line in FIG. 6, the boundary between the main body part 3 and the island-shaped part 5 is positioned inside the island-shaped p region 25. The island-shaped p region 25 is an example of a fourth semiconductor region in the claims. The p-type impurity concentration of the island-shaped p region 25 is lower than the p-type impurity concentration of the island-shaped p⁺ region 26. The p-type impurity concentration of the island-shaped p region 25 is, for example, about the same as the p-type impurity concentration of the p region 23.

The island-shaped p⁺ region 26 is a p⁺-type semiconductor region. The island-shaped p⁺ region 26 is a semiconductor region similar to the p⁺ region 24. That is, the island-shaped p⁺region 26 is provided inside the island-shaped part 5 from the island-shaped p region 25 up to the upper end of the island-shaped part 5. In addition, the island-shaped p⁺ region 26 is in contact with the island-shaped p region 25 and spaced from the n region 21 by the island-shaped p region 25. The island-shaped p⁺ region 26 is an example of a fifth semiconductor region in the claims. The p-type impurity concentration of the island-shaped p⁺ region 26 is higher than the p-type impurity concentration of the island-shaped p region 25. The p-type impurity concentration of the island-shaped p⁺ region 26 is, for example, about the same as the p-type impurity concentration of the p⁺ region 24. In the present embodiment, the island-shaped p⁺ region 26 is provided up to side ends of the island-shaped part 5.

In the example of FIG. 6, the positions of the upper end and the lower end of the island-shaped p region 25 are positioned at the same heights as the positions of the upper end and the lower end of the p region 23, respectively. Without being limited thereto, the position of at least one of the upper end or the lower end of the island-shaped p region 25 may be positioned at a height different from the position of at least one of the upper end or the lower end of the p region 23.

Similarly, in the example of FIG. 6, the positions of the upper end and the lower end of the island-shaped p⁺ region 26 are positioned at the same heights as the positions of the upper end and the lower end of the p⁺ region 24, respectively. Without being limited thereto, the position of at least one of the upper end or the lower end of the island-shaped p⁺ region 26 may be positioned at a height different from the position of at least one of the upper end or the lower end of the p⁺ region 24.

The ohmic electrode part 63 is provided over the island-shaped part 5. The ohmic electrode part 63 is in ohmic contact with the island-shaped p⁺ region 26 at least at the upper end of the island-shaped part 5. In the present embodiment, the ohmic electrode part 63 is in ohmic contact with the island-shaped p⁺ region 26 at the side ends of the island-shaped part 5, in addition to the upper end of the island-shaped part 5. In addition, the ohmic electrode part 63 is electrically connected to the anode electrode 11 via the Schottky electrode part 61. The ohmic electrode part 63 is an example of a third conductive part in the claims. The ohmic electrode part 63 contains, for example, nickel silicide (NiSi), titanium silicide (TiSi), or the like. The ohmic electrode part 63 may be made of the same material as the ohmic electrode part 62. In addition, the ohmic electrode part 63 may be in ohmic contact with the island-shaped p⁺ region 26 at a part of the side ends of the island-shaped part 5 in addition to the upper end of the island-shaped part 5.

As illustrated in FIG. 6, the Schottky electrode part 61 is also provided on the upper side of the ohmic electrode part 63.

According to the second embodiment described above, since the island-shaped part 5 is provided, the surge withstand capability of the semiconductor device 1B can be further improved.

The semiconductor device 1B can be manufactured by a method similar to that of the semiconductor device 1 according to the first embodiment. More specifically, the island-shaped part 5 is formed through the process similar to that of the protruding part 4, the island-shaped p region 25 is formed through the process similar to that of the p region 23, the island-shaped p⁺ region 26 is formed through the process similar to that of the p⁺ region 24, and the ohmic electrode part 63 is formed through the process similar to that of the ohmic electrode part 62.

The island-shaped part 5 may be formed together with the formation of the protruding part 4, the island-shaped p region 25 may be formed together with the formation of the p region 23, the island-shaped p⁺ region 26 may be formed together with the formation of with the p⁺ region 24, and the ohmic electrode part 63 may be formed together with the formation of the ohmic electrode part 62. For example, by forming the island-shaped part 5 together with the formation of the protruding part 4, the height of the upper end of the island-shaped part 5 can be made the same as the height of the upper end of the protruding part 4.

### Modification of Second Embodiment

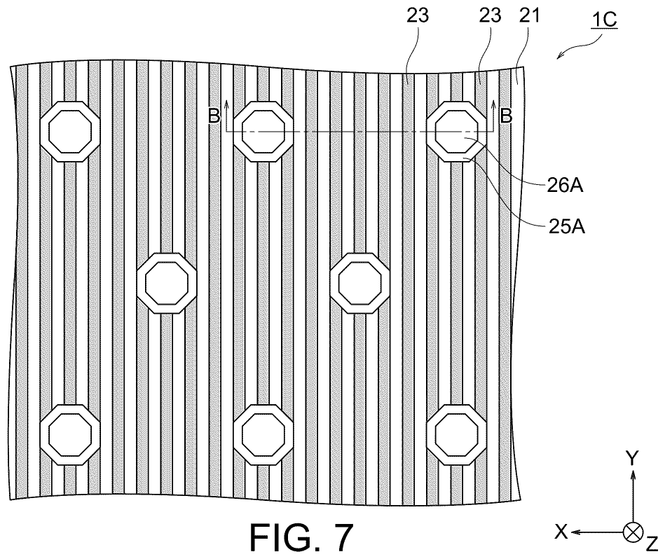

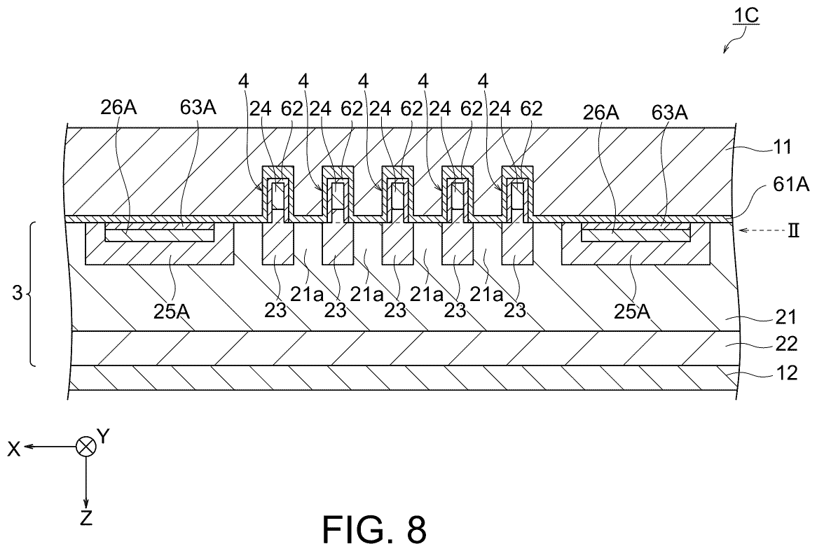

A semiconductor device 1C according to a modification of the second embodiment will be described with reference to FIGS. 7 and 8. FIG. 7 is a plan view of the semiconductor device 1C according to the modification of the second embodiment, and illustrates a plan view at a height position II in FIG. 8. FIG. 8 is a cross-sectional view of the semiconductor device 1C according to the modification of the second embodiment, taken along line B-B in FIG. 7. The semiconductor device 1C corresponds to a case where dot-shaped p region and p⁺ region are provided not in an island-shaped part 5 but in a main body part 3 in the semiconductor device 1B according to the second embodiment described above. Hereinafter, the semiconductor device 1C according to the present modification will be described focusing on the differences from the semiconductor device 1 according to the first embodiment.

As illustrated in FIGS. 7 and 8, the semiconductor device 1C according to the present modification further includes an island-shaped p region 25A, an island-shaped p⁺ region 26A, and an ohmic electrode part 63A, in addition to the configuration of the semiconductor device 1 according to the first embodiment. In addition, the semiconductor device 1C includes a Schottky electrode part 61A instead of the Schottky electrode part 61 of the semiconductor device 1.

The island-shaped p region 25A is a p-type semiconductor region. The island-shaped p region 25A is provided inside the main body part 3 of a silicon carbide layer and is positioned on an n region 21. The island-shaped p region 25A is an example of a sixth semiconductor region in the claims. The p-type impurity concentration of the island-shaped p region 25A is lower than the p-type impurity concentration of the island-shaped p⁺ region 26A. The p-type impurity concentration of the island-shaped p region 25A is, for example, about the same as the p-type impurity concentration of the p region 23. In the example of FIG. 8, a part of the island-shaped p region 25A includes the upper surface of the main body part 3.

The island-shaped p⁺ region 26A is a p⁺-type semiconductor region. The island-shaped p⁺ region 26A is provided inside the main body part 3 of the silicon carbide layer and is positioned on the island-shaped p region 25A. The island-shaped p⁺ region 26A includes the upper surface of the main body part 3. In addition, the island-shaped p⁺ region 26A is in contact with the island-shaped p region 25A and spaced from the n region 21 by the island-shaped p region 25A. In the example of FIG. 8, the lower end and the side ends of the island-shaped p⁺ region 26A are covered with the island-shaped p region 25A. The island-shaped p⁺ region 26A is an example of a seventh semiconductor region in the claims. The p-type impurity concentration of the island-shaped p⁺ region 26A is higher than the p-type impurity concentration of the island-shaped p region 25A. The p-type impurity concentration of the island-shaped p⁺ region 26A is, for example, about the same as the p-type impurity concentration of the p⁺ region 24.

The ohmic electrode part 63A is provided on the island-shaped p⁺ region 26A. The ohmic electrode part 63A is in ohmic contact with the island-shaped p⁺ region 26A at the upper surface of the main body part 3, more specifically, at the upper end of the island-shaped p⁺ region 26A. In addition, the ohmic electrode part 63A is electrically connected to the anode electrode 11 via the Schottky electrode part 61A. The ohmic electrode part 63A is an example of a fourth conductive part in the claims. The ohmic electrode part 63A contains, for example, nickel silicide (NiSi), titanium silicide (TiSi), or the like. The ohmic electrode part 63A may be made of the same material as the ohmic electrode part 62.

The Schottky electrode part 61A is a conductive part provided on the upper surface of the main body part 3. More specifically, the Schottky electrode part 61A covers the upper surface of the main body part 3 exposed between the protruding parts 4, the upper surface of the ohmic electrode part 62, the side surfaces of the ohmic electrode part 62, and the upper surface of the ohmic electrode part 63A. The Schottky electrode part 61A is electrically connected to the anode electrode 11. The Schottky electrode part 61A is made of, for example, the same material as that of the Schottky electrode part 61.

According to the modification of the second embodiment described above, the surge withstand capability of the semiconductor device 1C can be further improved.

The semiconductor device 1C can be manufactured by a method similar to that of the semiconductor device 1 according to the first embodiment. More specifically, the island-shaped p region 25A is formed similarly to that of the p region 23, the island-shaped p⁺ region 26A is formed through the process similar to that of the p⁺ region 24, and the ohmic electrode part 63A is formed through the process similar to that of the ohmic electrode part 62.

Note that the island-shaped p⁺ region 26A may be formed together with the formation of the p⁺ region 24. Alternatively, in order to position the lower end of the island-shaped p⁺ region 26A to be below the lower end of the p⁺ region 24, the island-shaped p⁺ region 26A may be formed in a different process from the p⁺ region 24, or ion implantation of p-type impurities may be additionally performed at the position of the island-shaped p⁺ region 26A.

On the other hand, the island-shaped p region 25A may be formed together with the formation of the p region 23, and the ohmic electrode part 63A may be formed together with the formation of the ohmic electrode part 62.

### Third Embodiment

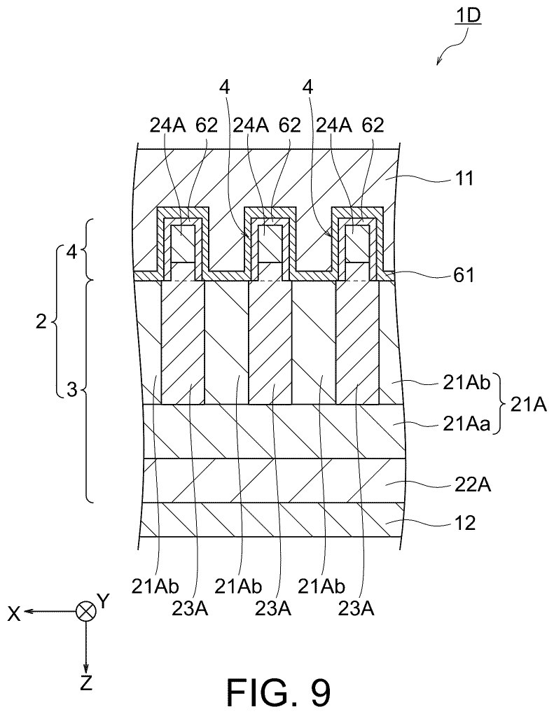

A semiconductor device 1D according to a third embodiment will be described with reference to FIG. 9. FIG. 9 is a cross-sectional view of the semiconductor device 1D according to the third embodiment. The semiconductor device 1D corresponds to a case where the semiconductor device 1 according to the first embodiment has a super-junction structure (SJ structure). Hereinafter, the semiconductor device 1D according to the present embodiment will be described focusing on the differences from the semiconductor device 1 according to the first embodiment.

As illustrated in FIG. 9, the semiconductor device 1D includes an n region 21A, an n⁺⁺ region 22A, a p⁺ region 23A, and a p⁺⁺ region 24A instead of the n region 21, the n⁺ region 22, the p region 23, and the p⁺ region 24 of the semiconductor device 1 according to the first embodiment.

The n region 21A includes a first portion 21Aa positioned below the p⁺ region 23A and a second portion 21Ab that is sandwiched between the adjacent p⁺ regions 23A and has an upper end positioned to be aligned with the upper surface of the main body part 3. An upper end of the second portion 21Ab is in contact with a Schottky electrode part 61 and in Schottky contact with the Schottky electrode part 61. In the present embodiment, a plurality of second portions 21Ab is provided.

The first portion 21Aa is, for example, an n-type semiconductor region. The n-type impurity concentration of the first portion 21Aa is lower than the n-type impurity concentration of the second portion 21Ab. The n-type impurity concentration of the first portion 21Aa is, for example, 3×10¹⁵ cm⁻³ or more and 2×10¹⁶ cm⁻³ or less. The height of the n region 21A, that is, the combined length of the first portion 21Aa and the second portion 21Ab in the Z-axis direction is, for example, 5.0 μm or more and 30.0 μm or less.

The second portion 21Ab is, for example, an n⁺-type semiconductor region. The n-type impurity concentration of the second portion 21Ab is higher than the n-type impurity concentration of the first portion 21Aa. The n-type impurity concentration of the second portion 21Ab is, for example, 5×10¹⁶ cm⁻³ or more and 5×10¹⁷ cm⁻³ or less. The height of the second portion 21Ab, that is, the length in the Z-axis direction is, for example, 3.0 μm or more and 20.0 μm or less.

The n⁺⁺ region 22A is an n⁺⁺-type semiconductor region. The n-type impurity concentration of the n⁺⁺ region 22A is higher than the n-type impurity concentration of the second portion 21Ab.

The p⁺ region 23A is a p⁺-type semiconductor region and a pillar region in the SJ structure. The p-type impurity concentration of the p⁺ region 23A is, for example, 5×10¹⁶ cm⁻³ or more and 5×10¹⁷ cm⁻³ or less. The height of the p⁺ region 23A, that is, the length in the Z-axis direction is, for example, 3.0 μm or more and 20.0 μm or less. The height of the p⁺ region 23A is the same as the height of the second portion 21Ab. That is, the lower end of the p⁺ region 23A is positioned at the same height as the lower end of the second portion 21Ab.

Note that the impurity concentrations of the second portion 21Ab of the n region 21A and the p⁺ region 23A are appropriately adjusted depending on any one of a unipolar operation or a bipolar operation emphasized in the semiconductor device 1D, for example.

The p⁺⁺ region 24A is a p⁺-type semiconductor region. The p-type impurity concentration of the p⁺⁺ region 24A is higher than the p-type impurity concentration of the p⁺ region 23A.

According to the third embodiment described above, in the semiconductor device 1D, the rated forward voltage can be reduced, and the surge withstand capability can be further improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a silicon carbide layer that includes a main body part and a protruding part protruding from the main body part;
a first electrode that is provided on the protruding part;
a second electrode that is provided opposite to the first electrode with the main body part interposed between the first electrode and the second electrode;
a first semiconductor region with a first conductivity type that is provided inside the main body part, and electrically connected to the second electrode;
a second semiconductor region with a second conductivity type that is provided inside the protruding part;
a third semiconductor region with the second conductivity type that is provided inside the protruding part from the second semiconductor region up to an upper end of the protruding part, and has an impurity concentration higher than that of the second semiconductor region;
a first conductive part that is in Schottky contact with the first semiconductor region, and electrically connected to the first electrode; and
a second conductive part that is in ohmic contact with the third semiconductor region at the upper end of the protruding part, and electrically connected to the first electrode.

2. The semiconductor device according to claim 1, wherein
a plurality of the second semiconductor regions is provided, and
the first semiconductor region includes a plurality of portions, each being sandwiched between the plurality of second semiconductor regions adjacent to each other and having an upper end in contact with the first conductive part.

3. The semiconductor device according to claim 2, wherein
the silicon carbide layer further includes an island-shaped part that protrudes in an island shape toward a protruding part side of the main body part, and
the semiconductor device further comprises:
a fourth semiconductor region with the second conductivity type that is provided inside the island-shaped part;
a fifth semiconductor region with the second conductivity type that is provided inside the island-shaped part from the fourth semiconductor region up to an upper end of the island-shaped part, and has an impurity concentration higher than that of the fourth semiconductor region; and
a third conductive part that is in ohmic contact with the fifth semiconductor region at the upper end of the island-shaped part and electrically connected to the first electrode.

4. The semiconductor device according to claim 2, further comprising:
a sixth semiconductor region with the second conductivity type that is provided inside the main body part of the silicon carbide layer and positioned on the first semiconductor region;
a seventh semiconductor region with the second conductivity type that is provided inside the main body part of the silicon carbide layer, positioned on the sixth semiconductor region, spaced from the first semiconductor region by the sixth semiconductor region, and has an impurity concentration higher than that of the sixth semiconductor region; and
a fourth conductive part that is in ohmic contact with the seventh semiconductor region and electrically connected to the first electrode.

5. The semiconductor device according to claim 2, wherein
a plurality of the second semiconductor regions is provided, and
the first semiconductor region includes a first portion positioned below the second semiconductor region, and a second portion that is sandwiched between the plurality of second semiconductor regions adjacent to each other, has an upper end in contact with the first conductive part, and has an impurity concentration higher than the first portion.

6. The semiconductor device according to claim 1, wherein the third semiconductor region is spaced from the first semiconductor region by the second semiconductor region.

7. The semiconductor device according to claim 6, wherein
the silicon carbide layer further includes an island-shaped part that protrudes in an island shape toward a protruding part side of the main body part, and
the semiconductor device further comprises:
a fourth semiconductor region with the second conductivity type that is provided inside the island-shaped part;
a fifth semiconductor region with the second conductivity type that is provided inside the island-shaped part from the fourth semiconductor region up to an upper end of the island-shaped part, and has an impurity concentration higher than that of the fourth semiconductor region; and
a third conductive part that is in ohmic contact with the fifth semiconductor region at the upper end of the island-shaped part and electrically connected to the first electrode.

8. The semiconductor device according to claim 6, further comprising:
a sixth semiconductor region with the second conductivity type that is provided inside the main body part of the silicon carbide layer and positioned on the first semiconductor region;
a seventh semiconductor region with the second conductivity type that is provided inside the main body part of the silicon carbide layer, positioned on the sixth semiconductor region, spaced from the first semiconductor region by the sixth semiconductor region, and has an impurity concentration higher than that of the sixth semiconductor region; and
a fourth conductive part that is in ohmic contact with the seventh semiconductor region and electrically connected to the first electrode.

9. The semiconductor device according to claim 6, wherein
a plurality of the second semiconductor regions is provided, and
the first semiconductor region includes a first portion positioned below the second semiconductor region, and a second portion that is sandwiched between the plurality of second semiconductor regions adjacent to each other, has an upper end in contact with the first conductive part, and has an impurity concentration higher than the first portion.

10. The semiconductor device according to claim 1, wherein the second conductive part is in ohmic contact with the third semiconductor region at a side end of the protruding part.

11. The semiconductor device according to claim 10, wherein
the silicon carbide layer further includes an island-shaped part that protrudes in an island shape toward a protruding part side of the main body part, and
the semiconductor device further comprises:
a fourth semiconductor region with the second conductivity type that is provided inside the island-shaped part;
a fifth semiconductor region with the second conductivity type that is provided inside the island-shaped part from the fourth semiconductor region up to an upper end of the island-shaped part, and has an impurity concentration higher than that of the fourth semiconductor region; and
a third conductive part that is in ohmic contact with the fifth semiconductor region at the upper end of the island-shaped part and electrically connected to the first electrode.

12. The semiconductor device according to claim 10, further comprising:
a sixth semiconductor region with the second conductivity type that is provided inside the main body part of the silicon carbide layer and positioned on the first semiconductor region;
a seventh semiconductor region with the second conductivity type that is provided inside the main body part of the silicon carbide layer, positioned on the sixth semiconductor region, spaced from the first semiconductor region by the sixth semiconductor region, and has an impurity concentration higher than that of the sixth semiconductor region; and
a fourth conductive part that is in ohmic contact with the seventh semiconductor region and electrically connected to the first electrode.

13. The semiconductor device according to claim 10, wherein
a plurality of the second semiconductor regions is provided, and
the first semiconductor region includes a first portion positioned below the second semiconductor region, and a second portion that is sandwiched between the plurality of second semiconductor regions adjacent to each other, has an upper end in contact with the first conductive part, and has an impurity concentration higher than the first portion.

14. The semiconductor device according to claim 1, wherein
the silicon carbide layer further includes an island-shaped part that protrudes in an island shape toward a protruding part side of the main body part, and
the semiconductor device further comprises:
a fourth semiconductor region with the second conductivity type that is provided inside the island-shaped part;
a fifth semiconductor region with the second conductivity type that is provided inside the island-shaped part from the fourth semiconductor region up to an upper end of the island-shaped part, and has an impurity concentration higher than that of the fourth semiconductor region; and
a third conductive part that is in ohmic contact with the fifth semiconductor region at the upper end of the island-shaped part and electrically connected to the first electrode.

15. The semiconductor device according to claim 14, wherein
the protruding part extends in a second direction orthogonal to a first direction from the first electrode toward the second electrode, and
a length of the island-shaped part in a third direction orthogonal to the first direction and the second direction is longer than a length of the protruding part in the third direction.

16. The semiconductor device according to claim 1, further comprising:
a sixth semiconductor region with the second conductivity type that is provided inside the main body part of the silicon carbide layer and positioned on the first semiconductor region;
a seventh semiconductor region with the second conductivity type that is provided inside the main body part of the silicon carbide layer, positioned on the sixth semiconductor region, spaced from the first semiconductor region with by sixth semiconductor region, and has an impurity concentration higher than that of the sixth semiconductor region; and
a fourth conductive part that is in ohmic contact with the seventh semiconductor region and electrically connected to the first electrode.

17. The semiconductor device according to claim 1, wherein the protruding part extends in a second direction orthogonal to a first direction from the first electrode toward the second electrode.

18. The semiconductor device according to claim 1, wherein
a plurality of the second semiconductor regions is provided, and
the first semiconductor region includes a first portion positioned below the second semiconductor region, and a second portion that is sandwiched between the plurality of second semiconductor regions adjacent to each other, has an upper end in contact with the first conductive part, and has an impurity concentration higher than the first portion.

19. The semiconductor device according to claim 1, wherein the first conductive part contains molybdenum, titanium, vanadium, nickel, or platinum.

20. The semiconductor device according to claim 1, wherein the second conductive part contains nickel silicide or titanium silicide.
